(19) United States
(12) Patent Application Publication
(10) Pub. No.: US 2009/0008799 A1
(43) Pub. Date: Jan. 8, 2009

(54) Dual mirror chips, wafer including the dual mirror chips, multi-chip packages, methods of fabricating the dual mirror chip, the wafer, and multichip packages, and a method for testing the dual mirror chips

(75) Inventors: Byong-Kwon Lee, Goyang-si (KR); Uk-Rae Cho, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/216,401

(22) Filed: Jul. 3, 2008

(30) Foreign Application Priority Data
Jul. 4, 2007 (KR) 10-2007-0067135

(51) Int. Cl. H01L 23/52; H01L 21/00; G01R 31/26

(52) U.S. Cl. 257/777; 438/109; 324/765; 257/E23.141; 257/E21.001

(57) ABSTRACT

Example embodiments provide a dual mirror chip, a wafer including the dual mirror chip, multi-chip packages and methods of fabricating the same. Example embodiments also provide a method of testing the dual mirror chip. According to example embodiments, a dual mirror chip may include a first type chip with a first output pad portion on a first side of the first type chip and a first input pad portion on a second side of the first type chip. The dual mirror chip may also include a second type chip to the side of the first type chip. The second type chip may include a second input pad portion on a first side of the second type chip and a second output pad portion on a second side of the second type chip. The dual mirror chip may also include at least one conductive line connecting the input pad portions.

### PRIORITY STATEMENT

This application claims priority under 35 U.S.C. § 119 to Korean Patent Application No. 2007-67135, filed on Jul. 4, 2007, in the Korean Intellectual Property Office (KIPO), the entire contents of which are herein incorporated by reference.

### BACKGROUND

1. Field

Example embodiments relate to a dual mirror chip, a wafer including the dual mirror chip, and multi-chip packages including the dual mirror chips. Example embodiments also provide for methods of fabricating a dual mirror chip, fabricating a wafer including the dual mirror chip, fabricating a multi-chip package, and testing the dual mirror chip.

2. Description of the Related Art

In order to perform an operational test of a chip (e.g., a probe test) at a wafer-level, pads on a chip may be used to connect the chip to an external device. A number of probe pins in a probe card may contact the pads of the chip to test the chip's circuit.

The growing trend of miniaturizing chip size is leading to the production of relatively small chips. As the process improves, the number of chips produced in a wafer increases and the size of the circuits becomes relatively small. However, there is a limitation on reducing a distance between pads. There is also a limitation on the number of probe pins of a probe card and the channels of a test system for testing the probe card.

Because the speed of a test clock is relatively high and the number of channels for testing is increased, the cost of a test system may become relatively expensive because of the limitation on the speed of the test clock and channels which a test system can support. Therefore, the increase in cost associated with a test system increases the cost of chip production.

### SUMMARY

Example embodiments provide a dual mirror chip, a wafer including the dual type memory chip, and a multi-chip package. Example embodiments also provide for methods of fabricating the dual mirror chip, fabricating a multi-chip package, fabricating the wafer, and testing the dual mirror chip.

According to example embodiments, a dual mirror chip may include a first type chip including a first output pad portion on a first (for example, left) side of the first type chip and a first input pad portion on a second (for example, right) side of the first type chip. According to example embodiments, a dual mirror chip may also include a second type chip to the side (for example, right side) of the first type chip. The second type chip may include a second input pad portion on a first (for example, left) side of the second type chip and a second output pad portion on a second (for example, right) side of the second type chip. According to example embodiments, a dual mirror chip may also include at least one conductive line connecting the first input pad portion to the second input pad portion. According to example embodiments, a wafer may include the dual mirror chip.

According to example embodiments, a multi-chip package may include an underlying chip with pads on a first surface and an overlying chip stacked on the underlying chip. The overlying chip may include a second surface and the second surface may include a first output pad portion on a first side of the second surface and a first input pad portion on a second side of the second surface. According to example embodiments, at least one of the first output pad portion or the first input pad portion may be connected to the pads on the first surface.

According to example embodiments, a method of fabricating a multi-chip package may include forming a first type chip including a first output pad portion on a first (for example, left) side of the first type chip and a first input pad portion on a second (for example, right) side of the first type chip, forming a second type chip to the side (for example, right side) of the first type chip, the second type chip including a second input pad portion on a first (for example, left) side of the second type chip and a second output pad portion on a second (for example, right) side of the second type chip. A method of fabricating a multi-chip package, according to example embodiments, may also include forming a scribe line between the first type chip and the second type chip and connecting the first input pad portion with the second input pad portion with at least one conductive line. A method of fabricating a multi-chip package, according to example embodiments, may also include separating the first type chip from the second type chip by cutting along the scribe line, stacking at least one of the first type chip or the second type chip on an underlying chip, wherein the underlying chip includes pads on a first surface, and connecting pads of the first type chip or second type chip stacked on the underlying chip to the pads on the first surface. According to example embodiments, a method of fabricating a wafer may include the method of fabricating the dual mirror chip.

According to example embodiments, a method of fabricating a multi-chip package may include providing an underlying chip with pads on a first surface, stacking an overlying chip on the underlying chip, wherein the overlying chip includes a second surface. The second surface may include a first output pad portion on a first side of the second surface and a first input pad portion on a second side of the second surface. According to example embodiments, a method of fabricating a multi-chip package may also include connecting at least one of the first output pad portion or the first input pad portion to the pads on the first surface.

A method of testing the dual mirror chip, according to example embodiments, may include providing a dual mirror chip, wherein the dual memory chip includes a first type chip including a first output pad portion on a first (for example, left) side of the first type chip and a first input pad portion on a second (for example, right) side of the first type chip, a second type chip to the side (for example, right side) of the first type chip, the second type chip including a second input pad portion on a first (for example, left) side of the second type chip and a second output pad portion on a second (for example, right) side of the second type chip, and at least one conductive line connecting the first input pad portion to the second input pad portion. According to example embodiments, a method of testing the dual mirror chip may also include applying an input pattern to first input pads in the input pad portion with a probe needle to generate output values from the first and second type chips and comparing the output values of the first and second type chips with an estimated value.

### BRIEF DESCRIPTION OF THE DRAWINGS

Example embodiments will be more clearly understood from the following detailed description taken in conjunction with the accompanying drawings. FIGS. 1-9 represent non-limiting, example embodiments as described herein.

FIG. 1 is a wafer including a dual die according to example embodiments.

FIG. 2 is a block diagram of a dual die according to example embodiments.

FIG. 3 is a flow chart illustrating an operation of a dual die according to example embodiments shown in FIG. 2.

FIG. 4 is a block diagram of a dual die according to example embodiments.

FIG. 5 is a probe card according to example embodiments.

FIG. 6 is a test system including the example probe card shown in FIG. 5.

FIG. 7 is a multi-chip package according to example embodiments.

FIG. 8 is a multi-chip package according to example embodiments.

FIG. 9 is a multi-chip package according to example embodiments.

### DETAILED DESCRIPTION OF EXAMPLE EMBODIMENTS

Example embodiments will now be described more fully with reference to the accompanying drawings, in which example embodiments are shown. Example embodiments may, however, be embodied in different forms and should not be construed as limited to the embodiments set forth herein. Rather, these embodiments are provided so that this disclosure will be thorough and complete, and will fully convey the scope of example embodiments to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

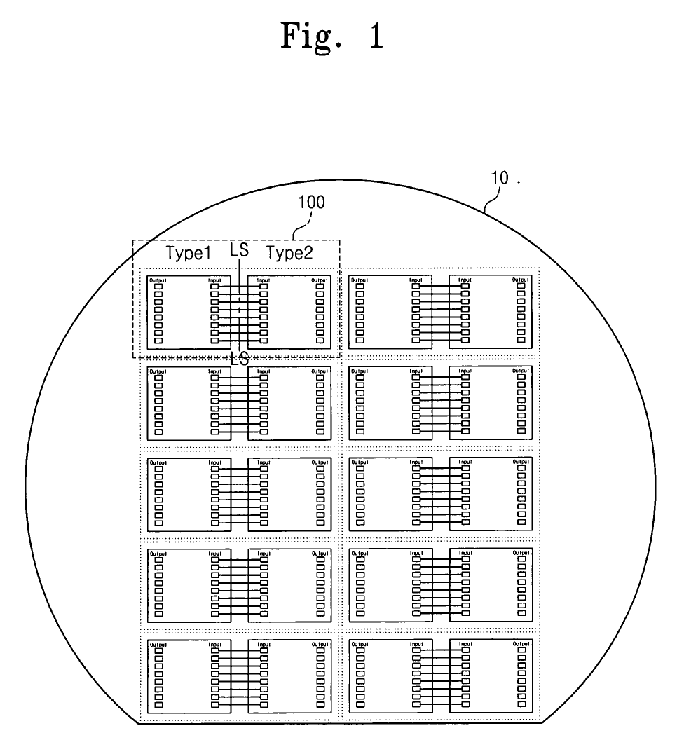

FIG. 1 is a wafer 10 including at least two dies according to example embodiments. Referring to FIG. 1, a wafer 10 may have a dual mirror chip including a first type chip (type 1) and a second type chip (type 2). The second type chip may have the same function as the first type chip. Output pads of the first type chip may be arranged on a first (for example, left) side of the first type chip and input pads of the first type chip may be arranged on a second (for example, right) side of the first type chip. Output pads of the second type chip may be arranged on a second (for example, right) side of the second type chip and input pads of the second type chip may be arranged on a first (for example, left) side of the second type chip. The pads of the resulting pair of chips may be symmetric with respect to the line of symmetry LS between the first type chip (type 1) and the second type chip (type 2). Therefore, the first type chip (type 1) may be a mirror image of the second type chip (type 2) with respect to input and output pads. Also, a mask (not shown) for producing a wafer 10 according to example embodiments may be designed so that two adjacent chips may be formed at the same time.

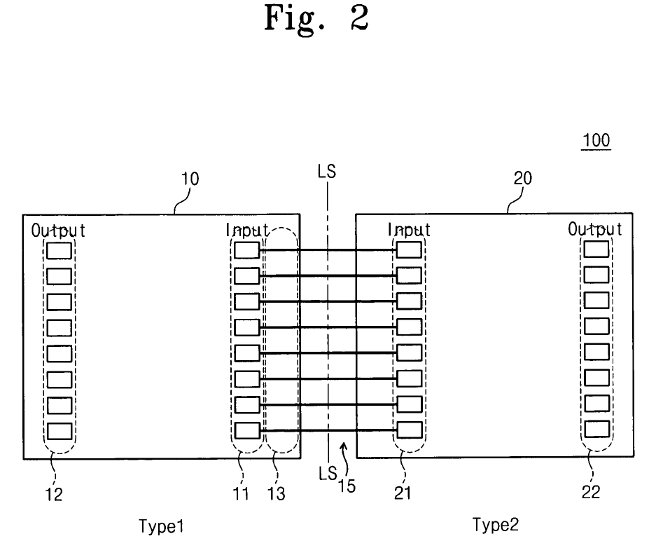

FIG. 2 is a block diagram according to example embodiments. Referring to FIG. 2, a dual mirror chip 100 may include a first type chip 10, a second type chip 20, a metal line portion 13 and a scribe line 15. The first type chip 10 may include an input pad portion 11 on a second (for example, right) side of the first type chip and an output pad portion 12 on a first (for example, left) side of the first type chip 10. The second type chip 20 may include an input pad portion 21 on a first (for example, left) side of the second type chip 20 and an output pad portion 22 on a second (for example, right) side of the second type chip 20. The metal line portion 13 may connect the input pad portion 11 of the first type chip 10 to the input pad portion 21 of the second type chip 20. The scribe line 15 may be a cut line for separating the first and second type chips 10 and 20 from the wafer 10.

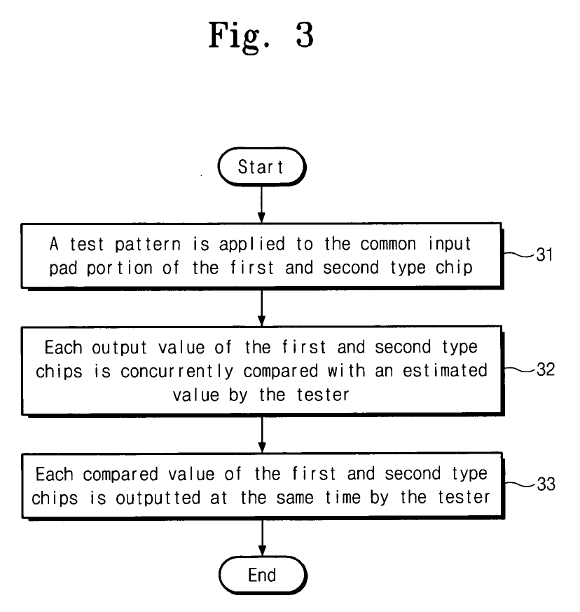

FIG. 3 is a flow chart illustrating an operation of example embodiments shown in FIG. 2. Referring to FIG. 3, a test pattern may be applied to the input pad portion 11 of the first type chip 10 from a tester (31). Because the input pad portion 21 of the second type chip 20 may be connected to the input pad portion 11 of the first type chip 10 through the metal line 13, the same test pattern may be applied to the second type chip 20.

The first and second type chips 10 and 20 may perform an operation in accordance with an inputted test pattern. Output operation results may be communicated through each output pad of the first and second type chips 10 and 20. Each output value of the first and second type chips 10 and 20 may be compared with an estimated value by the tester (32). Each compared value of the first and second type chips 10 and 20 may be outputted at the same time by the tester (33).

Because each of the first and second type chips 10 and 20 may include in-out pads, the in-out pads may be arranged in the same direction as the output pads. For example, in-out pads of the first type chip 10 may be arranged on a first (for example, left) and in-out pads of the second type chip 20 may be arranged on the side (for example, right side). Thus, a test pattern may be independently inputted to or outputted from the first and second type chips 10 and 20 through the in-out pads of the first and second type chips 10 and 20. The first and second type chips 10 and 20 may be cut on the basis of the scribe line 15 to remove the metal line 13 connecting the first and second type chips 10 and 20.

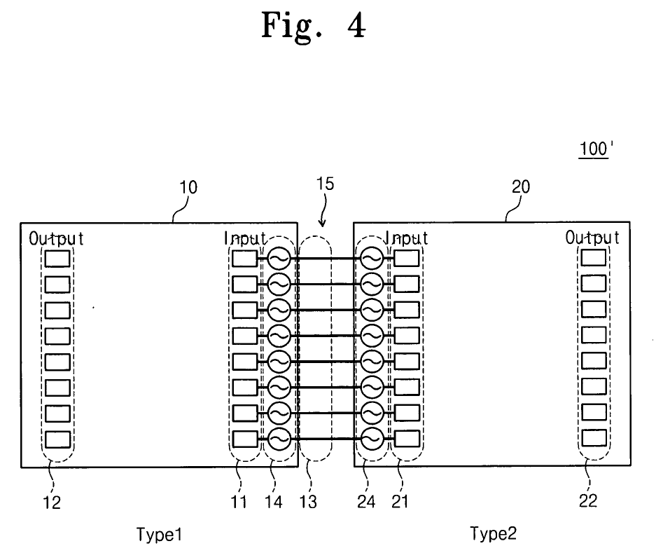

FIG. 4 is a block diagram in accordance with example embodiments. The scribe line 15 of the first and second type chips 10 and 20 in accordance with example embodiments may be cut and the metal line 13 may be pushed in a cutting direction of the metal line 13. A bridge phenomenon between the metal lines may occur because the metal line 13 has a ductility characteristic. If this bridge phenomenon occurs, the same signal may be applied to the bridged input pads. A fuse may be connected to the metal line in order to prevent or reduce the input pads from being electrically connected to each other.

A dual mirror chip 100′ according to example embodiments may be the same as the dual mirror chip 100 except for first fuses 14 and second fuses 24. Referring to FIG. 4, the dual mirror chip 100′ according to example embodiments may include the metal line 13. The metal line 13 may include first fuses 14 and second fuses 24. The first fuses 14 may be between the input pad portion 11 for the first type chip and the scribe line 15 in order to prevent or reduce bridging of the input pad portion 11 of the first type chip 10 due to a cutting of the scribe line 15. The second fuses 24 may be between the input pad portion 21 of the second type chip and the scribe line 15 in order to prevent or reduce bridging of the input pad portion 21 due to cutting the scribe line 15. The first and second fuses 14 and 24 according to the dual mirror chip 100′ of example embodiments may be cut using a laser.

According to example embodiments, the space between the input pads of the first and second type chips 10 and 20 and the scribe line 15 may be cut without using a coordinate value of the first and second fuses 14 and 24. For example, after sufficiently increasing an output of the laser, the metal line between the input pad portions of the first and second type chips 10 and 20 and the scribe line may be continuously cut using the laser.

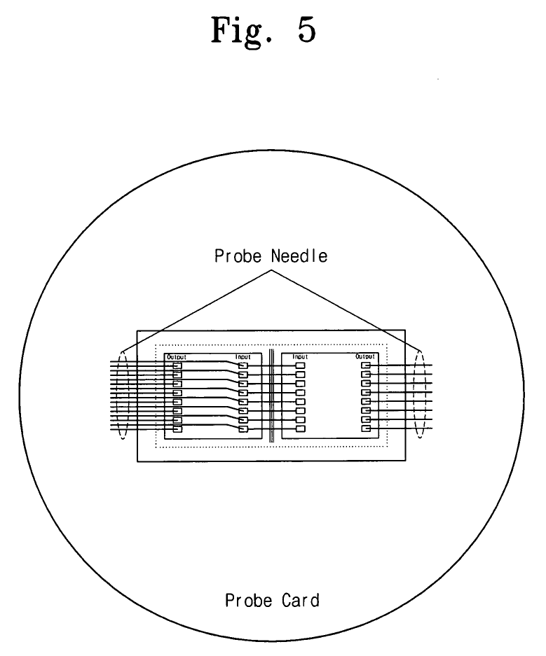

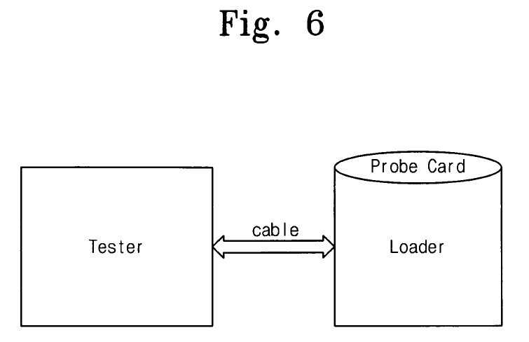

FIG. 5 is a probe card for testing example embodiments. FIG. 6 is a test system including the probe card shown in FIG. 5. Referring to FIGS. 5 and 6, the test system may include a probe card, a tester, and a loader. The probe card may connect the tester to a chip using a probe needle for testing a chip on the wafer 10. The loader may provide a wafer 10 to the probe card and may be connected to the tester through a cable. The probe card according to example embodiments may probe the dual mirror chips at the same time. The input pads of the first and second type chips may be connected to each other through the metal line 13. An input pattern for testing the first and second type chips may be applied to the first and second type chips through the probe needle.

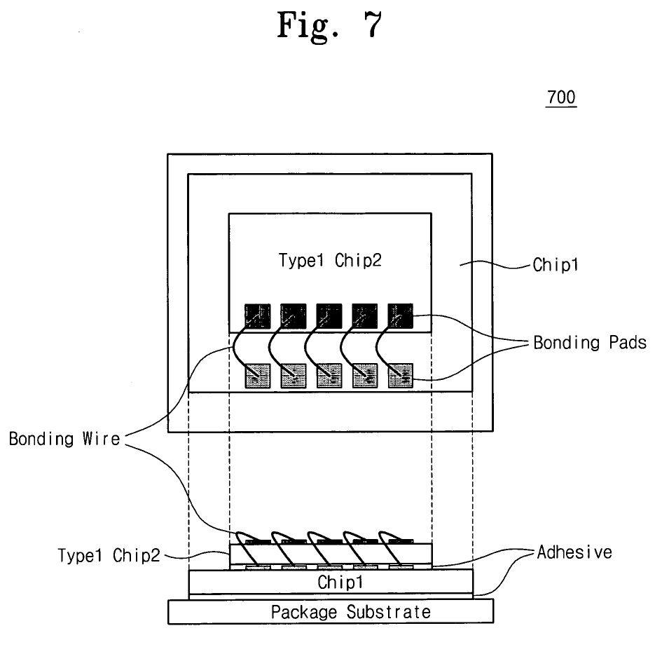

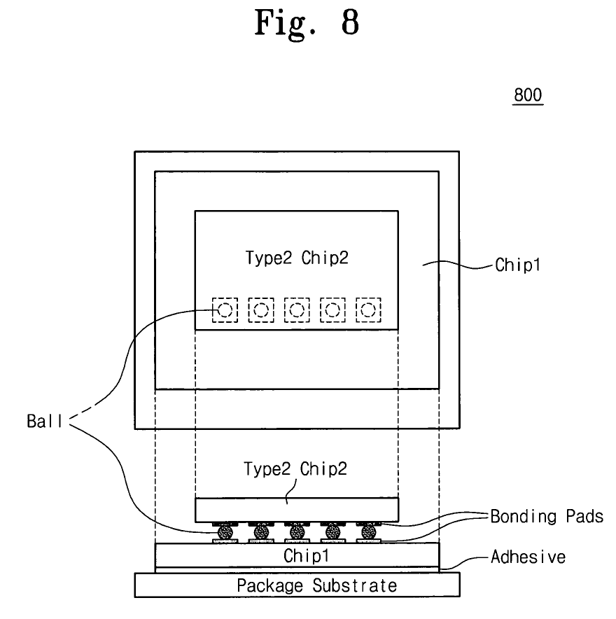

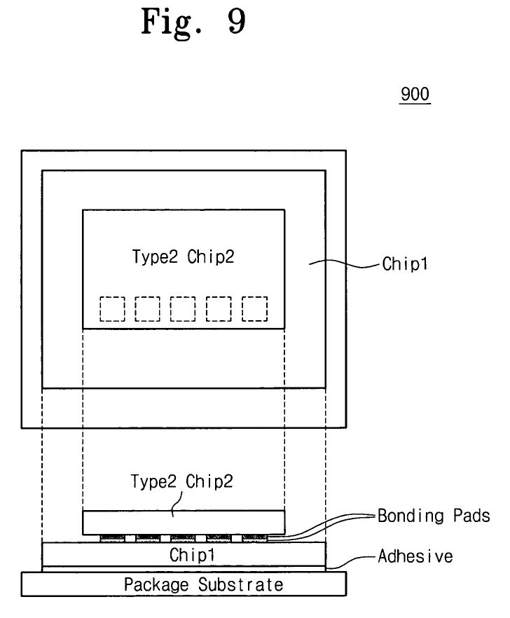

FIGS. 7, 8, and 9 illustrate multi-chip packages according to example embodiments. The multi-chip package shown in FIG. 7 may be used for a low speed operation. The multi-chip packages shown in FIGS. 8 and 9 may be a face to face type and may be used in a high speed operation. The multi-chip packages of the face to face type may be a multi-chip package that connects the overlying chip pads to the underlying chip pads so that the overlying chip and the underlying chip face each other. The first and second type chips according to example embodiments may have the same function and may be designed to have a bilateral symmetrical shape. An order of the first type chip pads may be symmetrical to an order of the second type chip pads.

Referring to FIG. 7, in the multi-chip package 700 according to example embodiments, an adhesive may be added on a package substrate and an underlying chip (chip 1) may be attached to the package substrate. An adhesive may be added on the underlying chip (chip 1) to attach the underlying chip (chip 1) to the substrate. An adhesive may also be added to attach the overlying chip (type 1 chip 2) to the underlying chip (chip 1). For example, the underlying chip (chip 1) and the overlying chip (type 1 chip 2) may be sequentially stacked. Pads of the underlying chip (chip 1) and the overlying chip (type 1 chip 2) may be connected by bonding wires.

In order to apply a chip used in a multi-chip package of a normal type to a multi-chip package of a high speed, the chip may require redesign because an order of pads of a chip used in a multi-chip package of a low speed may be opposite to an order of pads of a chip used in a multi-chip package of a high speed.

Multi-chip packages 800 and 900, shown in FIGS. 8 and 9, may be used for high speed operation. Referring to FIG. 8, an adhesive may be added on a package substrate and an underlying chip (chip 1) may be attached to the package substrate. The underlying chip (chip 1) may be connected to an overlying chip (type 2 chip 2) through balls. For example, the underlying chip (chip 1) and the overlying chip (type 2 chip 2) may be stacked so that the underlying chip (chip 1) and the overlying chip (type 2 chip 2) may be facing each other. Pads of the underlying chip (chip 1) may be connected to the pads of the overlying chip (type 2 chip 2) through the balls. In the multi-chip package 800 shown in FIG. 9, pads of an underlying chip (chip 1) may be directly attached to an overlying chip (type 2 chip 2) so that the pads of the underlying chip (chip 1) and the pads of the overlying chip (type 2 chip 2) face each other. The multi-chip packages 800 and 900 may be suitable for high speed operation because the pads of the underlying chip (chip 1) and the pads of the overlying chip (type 2 chip 2) may be connected to each other through the balls or directly.

An order of the pads of the overlying chip (type 1 chip2) in FIG. 7 may be opposite to an order of the pads of the overlying chip (type 2 chip2) in FIGS. 8 and 9. Accordingly, the dual mirror chip according to example embodiments may be able to be used in a low speed package and a high speed package. The first type chip may be used in the multi-chip package 700 requiring a low speed operation and the second type chip may be used in the multi-chip packages 800 and 900 requiring a high speed operation. Example embodiments may reduce a test time in a wafer level and may provide a multi-chip package that is applicable to a high speed operation and a low speed operation.

While example embodiments have been particularly shown and described with reference to example embodiments thereof, it will be understood by those of ordinary skill in the art that various changes in form and details may be made therein without departing from the spirit and scope of the following claims.

What is claimed is:

1. A dual mirror chip, comprising:
a first type chip including a first output pad portion on a first side of the first type chip and a first input pad portion on a second side of the first type chip;
a second type chip to the side of the first type chip, the second type chip including a second input pad portion on a first side of the second type chip and a second output pad portion on a second side of the second type chip; and
at least one conductive line connecting the first input pad portion to the second input pad portion.

2. The dual mirror chip of claim 1, further comprising:
a first fuse between the first input pad portion and the at least one conductive line; and
a second fuse between the second input pad portion and the at least one conductive line.

3. The dual mirror chip of claim 2, wherein the first and second fuses are fused by a laser.

4. The dual mirror chip of claim 1, further comprising:
a scribe line between the first type chip and the second type chip for separating the first type chip from the second type chip.

5. The dual mirror chip of claim 4, wherein the at least one conductive line is cut by cutting the scribe line.

6. The dual mirror chip of claim 1, wherein the first and second input pad portions are configured to receive a test pattern applied during a wafer test, and the first and second type chips are configured to respond to the applied test pattern to produce output values from the first and second output pad portions.

7. The dual mirror chip of claim 1, wherein the at least one conductive line is at least one metal line.

8. A wafer including the dual mirror chip of claim 1.

9. A multi-chip package, comprising:
an underlying chip with pads on a first surface; and
an overlying chip stacked on the underlying chip, wherein the overlying chip includes a second surface, the second surface including a first output pad portion on a first side of the second surface and a first input pad portion on a second side of the second surface and at least one of the first output pad portion or the first input pad portion is connected to the pads on the first surface.

10. The multi-chip package of claim 9, wherein the overlying chip is sequentially stacked on the underlying chip and at least one of the first output pad portion or the first input pad portion is connected to the pads on the first surface with at least one bonding wire.

11. The multi-chip package of claim 9, wherein the second surface faces the first surface and at least one of the first output pad portion or the first input pad portion is connected to the pads on the first surface by solder balls.

12. The multi-chip package of claim 9, wherein the second surface faces the first surface and at least one of the first output pad portion or the first input pad portion is directly connected to the pads on the first surface.

13. A method of fabricating a dual mirror chip, comprising:
forming a first type chip including a first output pad portion on a first side of the first type chip and a first input pad portion on a second side of the first type chip;
forming a second type chip to the second of the first type chip, the second type chip including a second input pad portion on a first side of the second type chip and a second output pad portion on a second side of the second type chip; and
connecting the first input pad portion with the second input pad portion with at least one conductive line.

14. The method of claim 13, further comprising:
providing a first fuse between the first input pad portion and the at least one metal line; and
providing a second fuse between the second input pad portion and the at least one metal line.

15. The method of claim 13, further comprising:
providing a scribe line between the first type chip and the second type chip for separating the first type chip from the second type chip.

16. The method of claim 13, wherein the at least one conductive line is at least one metal line.

17. A method of fabricating a wafer, comprising the method of fabricating a dual mirror chip according to claim 13.

18. A method of fabricating a multi-chip package, comprising:
providing an underlying chip with pads on a first surface;
stacking an overlying chip on the underlying chip, wherein the overlying chip includes a second surface, the second surface including a first output pad portion on a first side of the second surface and a first input pad portion on a second side of the second surface; and
connecting at least one of the first output pad portion or the first input pad portion to the pads on the first surface.

19. A method of fabricating a multi-chip package, comprising:
fabricating a dual mirror chip according to claim 15;
separating the first type chip from the second type chip by cutting along the scribe line;
stacking at least one of the first type chip or the second type chip on an underlying chip, wherein the underlying chip includes pads on a first surface; and
connecting pads of the first type chip or the second type chip stacked on the underlying chip to the pads on the first surface.

20. A method of testing the dual mirror chip, comprising:
providing a dual mirror chip, wherein the dual memory chip includes a first type chip including a first output pad portion on a first side of the first type chip and a first input pad portion on a second side of the first type chip, a second type chip to the side of the first type chip, the second type chip including a second input pad portion on a first side of the second type chip and a second output pad portion on a second side of the second type chip, and at least one conductive line connecting the first input pad portion to the second input pad portion;
applying an input pattern to first input pads in the input pad portion with a probe needle to generate output values from the first and second type chips; and
comparing the output values of the first and second type chips with an estimated value.
